(19) United States
(12) Patent Application Publication
(10) Pub. No.: US 2019/0136372 A1
(43) Pub. Date: May 9, 2019

(54) ATOMIC LAYER DEPOSITION COATINGS FOR HIGH TEMPERATURE HEATERS

(71) Applicant: Applied Materials, Inc., Santa Clara, CA (US)

(72) Inventors: Guodong Zhan, Dhahran (SA); David Fenwick, Los Altos Hills, CA (US); Jennifer Y. Sun, Mountain View, CA (US)

(21) Appl. No.: 16/101,329

(22) Filed: Aug. 10, 2018

Related U.S. Application Data
(60) Provisional application No. 62/545,162, filed on Aug. 14, 2017.

(51) Int. Cl. C23C 16/30; C23C 16/455; C23C 16/40

(52) U.S. Cl. CPC C23C 16/303; C23C 16/45525; F23M 2900/05001; F23M 2900/05004; C23C 16/40

(57) ABSTRACT

Embodiments of the disclosure relate to articles, coated chamber components and methods of coating chamber components with a low volatile coating. The low volatile coating can include a rare earth metal-containing layer that coats all surfaces of a component (e.g., a high temperature heater).

### CROSS-REFERENCE TO RELATED APPLICATION(S)

This application claims the benefit of provisional U.S. Application No. 62/545,162 filed on Aug. 14, 2017.

### TECHNICAL FIELD

Embodiments of the disclosure relate to articles, coated chamber components and methods of coating chamber components with a low volatile coating. The low volatile coating can include a rare earth metal-containing layer that coats all surfaces of a component (e.g., a high temperature heater).

### BACKGROUND

Various semiconductor manufacturing processes use high temperatures, high energy plasma, a mixture of corrosive gases, high stress, and combinations thereof. These extreme conditions may result in a reaction between materials of components within the chamber and the plasma or corrosive gases to form high vapor pressure gases. Such gases may readily sublime and deposit on other components within the chamber. During a subsequent process step, the deposited material may release from the other components as particles and fall onto the wafer causing defects. It is desirable to reduce these defects with a low volatile coating on the reactive materials to limit the sublimation and/or deposition of reactants on components within the chamber.

Protective coatings are typically deposited on chamber components by a variety of methods, such as thermal spray, sputtering, plasma spray or evaporation techniques. These techniques generally cannot deposit conformal, uniform coatings onto complex topographical features of a component with the low defect density of ALD coatings. Additionally, these techniques are generally not suitable for coating heater components without noticeably impacting the performance of the heater because relatively thick coatings would be required to achieve the same level of protection for the heater as that provided by thinner, lower-defect density ALD films.

### SUMMARY

Described in embodiments herein is an article comprising a component comprising a heater material with a thermal conductivity of about 50 W/mK to about 300 W/mK; and a low volatile coating on a surface of the heater material, the low volatile coating having a thickness of about 5 nm to about 5 μm, wherein the low volatile coating comprises a rare earth metal, and wherein the heater material with the low volatile coating has the thermal conductivity or an adjusted thermal conductivity that is within about ±5% of the thermal conductivity of the heater material without the low volatile coating.

Described in further embodiments herein is a method comprising performing atomic layer deposition (ALD) to deposit a low volatile coating on a component comprising a heater material with a thermal conductivity of about 50 W/mK to about 300 W/mK, wherein the low volatile coating has a thickness of about 5 nm to about 5 μm, wherein the low volatile coating reacts with a plasma to form reactants having a lower vapor pressure than reactants formed by reaction of the heater material with the plasma, and wherein the heater material with the low volatile coating has the thermal conductivity or an adjusted thermal conductivity that is within about ±5% of the thermal conductivity of the heater material without the low volatile coating.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of a processing chamber.

FIG. 2 depicts a heater assembly with components having a low volatile coating in accordance with embodiments.

FIG. 3A depicts one embodiment of a deposition process in accordance with an atomic layer deposition technique as described herein.

FIG. 3B depicts another embodiment of a deposition process in accordance with an atomic layer deposition technique as described herein.

FIG. 3C depicts another embodiment of a deposition process in accordance with an atomic layer deposition technique as described herein.

FIG. 4A illustrates a method for creating a plasma resistant coating using atomic layer deposition as described herein.

FIG. 4B illustrates a method for creating a plasma resistant coating using atomic layer deposition as described herein.

### DETAILED DESCRIPTION

Embodiments described herein cover articles, coated chamber components and methods where a low volatile coating is deposited onto a heater (e.g., an aluminum nitride heater) without substantially affecting the thermal conductivity and heat capacity properties or other material properties of the heater materials. The coating may be formed of a material that reacts with reactive plasma in the chamber to form a reactant having a low vapor pressure (e.g., and/or which may have a high melting point) that does not significantly sublime or deposit onto components within the chamber. The low volatile coating may be a rare earth metal-containing layer (e.g., a yttrium-containing oxide layer or a yttrium-containing fluoride layer). The low volatile coating may alternatively be a multi-layer coating that includes one or more adhesion layer and one or more stack layer with alternating thin layers of a metal oxide or nitride and a rare earth metal-containing material. As used herein, the term “low volatile coating” means a coating that, when exposed to a plasma at a high temperature, will react with the plasma to form a low-vapor pressure metal gas (e.g., metal fluorides). In embodiments, the vapor pressure of the lower-vapor pressure metal gas will be at least one order of magnitude lower than that of gases formed when the plasma reacts with the material of the uncoated heater in the same environment (e.g., under the same conditions and using the same method of measurement). The article may include an aluminum nitride material. The deposition process may be a non-line of sight process such as an atomic layer deposition (ALD) process.

In certain embodiments, the thickness of the low volatile coating may be about 5 nm to about 10 μm, or about 25 nm to about 5 μm, or about 50 nm to about 500 nm, or about 75 nm to about 200 nm. In some embodiments, the thickness of the low volatile coating may be about 50 nm, or about 75 nm, or about 100 nm, or about 125 nm, or about 150 nm. The low volatile coating may conformally cover a surface of a heater with a substantially uniform thickness. In one embodiment, the thermal conductivity of the coated heater material is within ±5% of the thermal conductivity of the heater material without the low volatile coating. In one embodiment, the thermal conductivity of the coated heater material is the same as the thermal conductivity of the heater material without the low volatile coating. In one embodiment, the heat capacity of the heater material with the low volatile coating is within ±5% of the heat capacity of the heater material without the low volatile coating. In one embodiment, the low volatile coating has a conformal coverage of the underlying surface that is coated with a uniform thickness having a thickness variation of less than ±20%, or a thickness variation of less than ±10%, or a thickness variation of less than ±5%, or a lower thickness variation.

Embodiments described herein improve the volatility and reactivity properties of heater materials when exposed to plasmas. Certain components, for example, a high temperature heater (i.e., a heater capable of reaching about 650° C.), may contain materials selected for their advantageous thermal conductivity and heat capacity properties. Such materials (e.g., aluminum nitride) may be volatile in the presence of certain plasmas (e.g., a nitrogen trifluoride plasma) where the materials react with the plasma to form a compound having a high vapor pressure. Such compounds may sublime and deposit on other chamber components and flake (as particles) during a subsequent process step resulting in particle defects on the wafer. For example, AlN can react with fluorine plasmas (e.g., NF₃) in the process chamber during a cleaning step to form AlF₃. The AlF₃ has a high vapor pressure so that this reactant sublimes and deposits on other components within the chamber. During a subsequent process step, the deposited AlF₃ flakes, peels or otherwise detaches from the other chamber components and contaminates the wafer therein with particles. The AlF₃ sublimation can occur at a temperature of 300° C. under low chamber pressures although it is more severe at temperatures over 600° C. Coating AlN heater materials with MgF₂/YF₃ plasma sprayed coatings can be fluorine plasma resistant, but such coatings wear away very fast during wafer processing. Coating AlN heater materials with a low volatile coating as described herein may protect the heater materials (e.g., at high temperatures of about 650° C.) and result in reactant products, for example, metal fluorides (MFₓ), having a relatively low vapor pressure (e.g., which may also have a high melting point), which inhibits this sublimation and deposition.

The low volatile coating, however, should not significantly affect the heating properties (e.g., the thermal conductivity, heat capacity, temperature) of the heater materials so that the performance of the component is maintained. In accordance with embodiments herein, the coated heater materials have a thermal conductivity or heat capacity that is within ±5% of the thermal conductivity or heat capacity, respectively, of the heater materials without the coating. Additionally, the coating technique for depositing the adhesion and stack layers may be a non-line of sight process that can penetrate into the three-dimensional geometry of the components and cover all exposed internal and external surfaces.

The heater may be formed from an aluminum nitride (AlN) material or other suitable material having a comparable chemical resistance and mechanical, thermal and electrical properties. The heater material may have embedded therein wires (e.g., tungsten wires) to supply electricity. In embodiments, the heater material may be an AlN ceramic, a silicon carbide (SiC) ceramic, an aluminum oxide (Al₂O₃) ceramic or any combination thereof. Different heater materials may have different reaction properties such that one composition may form a reactant with a higher vapor pressure than another composition when exposed to high temperatures, low vacuum pressures and aggressive chemistries. For example, when a typical high temperature heater having an AlN material ceramic is exposed to nitrogen trifluoride (NF₃) plasma under high temperature (e.g., up to about 650° C.) and vacuum conditions (e.g., about 50 mTorr to about 200 mTorr), the reaction produces aluminum trifluoride (AlF₃), which has a vapor pressure of about log (p/kpa)=11.70−14950 (T/K). The AlF₃ is thus able to sublime and deposit onto other components within the chamber. During a subsequent process step, the deposited material may peel or flake or otherwise detach from the other chamber components and deposit as particles onto a wafer therein resulting in defects. A low volatile coating (e.g., a rare earth metal-containing layer) on the AlN ceramic heater material may result in reactant products having a relatively lower vapor pressure (e.g., yttrium fluoride or YF₃) so that the reactants are inhibited from subliming or depositing onto the other chamber components. The low volatile coating may also be dense with a porosity of about 0% (e.g., the low volatile coating may be porosity-free in embodiments). The low volatile coatings also may be resistant to corrosion and erosion from plasma etch chemistries, such as CCl₄/CHF₃ plasma etch chemistries, HCl₃Si etch chemistries and NF₃ etch chemistries.

ALD allows for a controlled self-limiting deposition of material through chemical reactions with the surface of the article. Aside from being a conformal process, ALD is also a uniform process and is capable of forming very thin films, for example, having a thickness of about 3 nm or more. All exposed surfaces of the article will have the same or approximately the same amount of material deposited. As set forth herein, the heater may have the same or substantially the same thermal conductivity and heating capacity as the uncoated heater. A typical reaction cycle of an ALD process starts with a precursor (i.e., a single chemical A) flooded into an ALD chamber and adsorbed onto surfaces of the article (including surfaces of pore walls within the article). The excess precursor is then flushed out of the ALD chamber before a reactant (i.e., a single chemical R) is introduced into the ALD chamber and subsequently flushed out. For ALD, the final thickness of material is dependent on the number of reaction cycles that are run, because each reaction cycle will grow a layer of a certain thickness that may be one atomic layer or a fraction of an atomic layer.

The ALD technique can deposit a thin layer of material at a relatively low temperature (e.g., about 25° C. to about 350° C.) so that it does not damage or deform any materials of the component. Additionally, the ALD technique can also deposit a layer of material within complex features (e.g., high aspect ratio features) of the component. Furthermore, the ALD technique generally produces relatively thin (i.e., 1 μm or less) coatings that are porosity-free (i.e., pin-hole free), which may eliminate crack formation during deposition.

Various process chamber components, such as high temperature heaters or other components formed of materials having similar properties to AlN, would benefit from having low volatile coatings to protect the components in harsh plasma environments while not impacting their performance. Conventional line-of-sight deposition methods would require thicker coatings than those deposited by ALD to achieve a given level of protection for the heater. Thicker coatings could potentially affect the thermal properties (e.g., thermal conductivity, heat capacity, temperature) of the components and therefore impact their performance. Thus, an achievement of some embodiments herein is to apply a low volatile coating to heater materials of a high temperature heater without substantially affecting (e.g., no change or within ±5%) the thermal properties of the heater materials. Applying, for example, a rare earth metal-containing coating to a component, such as a high temperature heater, at a thickness of, for example, about 50 nm to about 150 nm, or about 100 nm, may substantially reduce deposits on other chamber components during plasma cleaning and thus, may reduce particle defects.

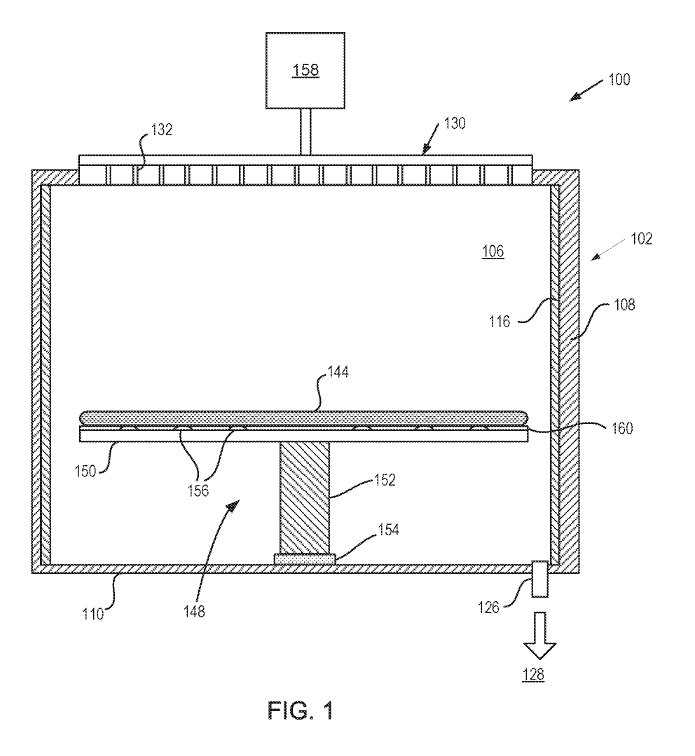

FIG. 1 is a sectional view of a semiconductor processing chamber 100 having one or more chamber components that are coated with a plasma resistant coating in accordance with embodiments. The base materials of the chamber may include one or more of aluminum (Al), titanium (Ti) and stainless steel (SST). The processing chamber 100 may be used for processes in which a corrosive plasma environment having plasma processing conditions is provided. For example, the processing chamber 100 may be a chamber for a plasma etcher or plasma etch reactor, a plasma cleaner, plasma enhanced CVD or ALD reactors and so forth. An example of a chamber component that may include a low volatile coating is a high temperature heater. The low volatile coating, which is described in greater detail below, is applied by ALD. ALD allows for the application of a conformal coating of a substantially uniform thickness that is porosity-free on all types of components with complex shapes and features having high aspect ratios.

The low volatile coating comprising a rare earth metal may be grown or deposited using ALD with a rare earth metal-containing precursor and a reactant consisting of or containing oxygen, fluorine or nitrogen. The rare earth metal-containing precursor may contain yttrium, erbium, lanthanum, lutetium, scandium, gadolinium, samarium or dysprosium. The low volatile coating may additionally or alternatively be grown or deposited using ALD with a precursor for deposition of an adhesion layer having the same or a similar material to the underlying component material to be deposited. For example, an aluminum-containing precursor and nitrogen containing reactant may be used to form AlN, or an aluminum-containing precursor and oxygen-containing reactant may be used to form aluminum oxide (Al₂O₃). A stack or wear resistant layer may be grown or deposited on top of the adhesion layer using ALD with one or more precursors containing a rare earth metal as set forth above. In some embodiments, the wear resistant layer can be deposited using sputtering, ion assisted deposition, plasma spray coating or chemical vapor deposition. As described in more detail below, the stack layer may have alternating thin layers of the rare earth metal-containing material and another oxide or nitride material, such as Al₂O₃ or AlN. In one embodiment, the rare earth metal-containing layer has a polycrystalline structure. Alternatively, the rare earth metal-containing layer may have an amorphous structure. The rare earth metal-containing layer may include yttrium, erbium, lanthanum, lutetium, scandium, gadolinium, samarium and/or dysprosium. For example, the rare earth metal-containing layer may include yttria (Y₂O₃), yttrium fluoride (YF₃), yttrium oxyfluoride (YₓO_{y}F_{z} or YOF), erbium oxide (Er₂O₃), erbium fluoride (EF₃), erbium oxyfluoride (EₓO_{y}F_{z}), dysprosium oxide (Dy₂O₃), dysprosium fluoride (DyF₃), dysprosium oxyfluoride (DyₓO_{y}F_{z}), gadolinium oxide (Gd₂O₃), gadolinium fluoride (GdF₃), gadolinium oxyfluoride (GdₓO_{y}F_{z}), scandium oxide (Sc₂O₃), scandium fluoride (ScF₃), scandium oxyfluoride (ScₓO_{y}F_{z}) and so on. In embodiments, the rare-earth metal layer is polycrystalline Y₂O₃, YF₃ or YₓO_{y}F_{z}. The values of x, y and z may be fractional values or whole values (e.g., 1, 2, 3, 4, 5, 6, 7, 8, 9, 10, 11, 12, etc.). In other embodiments, the rare-earth metal layer is amorphous Y₂O₃, YF₃ or YₓO_{y}F_{z}. In an embodiment, the rare earth metal-containing material may be co-deposited with another material. For example, a rare earth metal-containing oxide may be mixed with one or more other rare earth compounds such as Y₂O₃, gadolinium oxide (Gd₂O₃) and/or erbium (e.g., Er₂O₃). A yttrium-containing oxide for the low volatile coating may be, for example, YₓDy_{y}O_{z}, YₓGd_{y}O_{z} or YₓEr_{y}O_{z}. The yttrium-containing oxide may be Y₂O₃ having a cubic structure with space group Ia-3 (206).

In one embodiment, the rare-earth metal-containing layer is one of Y₂O₃, Y₃Al₅O₁₂ (YAG), Y₄Al₂O₉ (YAM), YF₃, YOF, Er₂O₃, Er₃Al₅O₁₂ (EAG), EF₃, EOF, La₂O₃, Lu₂O₃, Sc₂O₃, ScF₃, ScOF, Gd₂O₃, Sm₂O₃ or Dy₂O₃. The rare-earth metal-containing layer may also be YAlO₃ (YAP), Er₄Al₂O₉ (EAM), ErAlO₃ (EAP) or other ternary variants of lanthanum, lutetium, scandium, gadolinium, samarium or dysprosium. Any of the aforementioned rare-earth metal-containing materials may include trace amounts of other materials such as ZrO₂, Al₂O₃, SiO₂, B₂O₃, Er₂O₃, Nd₂O₃, Nb₂O₅, CeO₂, Sm₂O₃, Yb₂O₃, or other oxides.

In one embodiment, the processing chamber 100 includes a chamber body 102 and a showerhead 130 that encloses an interior volume 106. The showerhead 130 may include a showerhead base and a showerhead gas distribution plate. Alternatively, the showerhead 130 may be replaced by a lid and a nozzle in some embodiments, or by multiple pie shaped showerhead compartments and plasma generation units in other embodiments. The chamber body 102 may be fabricated from aluminum, stainless steel or other suitable material such as titanium (Ti). The chamber body 102 generally includes sidewalls 108 and a bottom 110. An outer liner 116 may be disposed adjacent the sidewalls 108 to protect the chamber body 102.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewall 108 of the chamber body 102. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through the showerhead 130 or lid and nozzle. Showerhead 130 may be used for processing chambers used for dielectric etch (etching of dielectric materials). The showerhead 130 may include a gas distribution plate (GDP) and may have multiple gas delivery holes 132 throughout the GDP. The showerhead 130 may include the GDP bonded to an aluminum base or an anodized aluminum base. The GDP may be made from Si or SiC, or may be a ceramic such as Y₂O₃, Al₂O₃, Y₃Al₅O₁₂ (YAG), and so forth.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound comprising Y₄Al₂O₉ and a solid-solution of Y₂O₃-ZrO₂. The nozzle may also be a ceramic, such as Y₂O₃, YAG, or the ceramic compound comprising Y₄Al₂O₉ and a solid-solution of Y₂O₃-ZrO₂.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases).

A heater assembly 148 is disposed in the interior volume 106 of the processing chamber 100 below the showerhead 130 or lid. The heater assembly 148 includes a support 150 that holds a substrate 144 during processing. The support 150 is attached to the end of a shaft 152 that is coupled to the chamber body 102 via a flange 154. The support 150, shaft 152 and flange 154 may be constructed of a heater material containing AlN, for example, an AlN ceramic. The support 150 may further include mesas 156 (e.g., dimples or bumps). The support may additionally include wires, for example, tungsten wires (not shown), embedded within the heater material of the support 150. In one embodiment, the support 150 may include metallic heater and sensor layers that are sandwiched between AlN ceramic layers. Such an assembly may be sintered in a high-temperature furnace to create a monolithic assembly. The layers may include a combination of heater circuits, sensor elements, ground planes, radio frequency grids and metallic and ceramic flow channels. The heater assembly 148 may provide a heater temperature up to about 650° C. under vacuum conditions (e.g., about 1 mTorr to about 5 Tons). A low volatile coating 160 in accordance with embodiments described herein may be deposited on the support 150 or on all surfaces of the heater assembly 148 (including the support 150, shaft 152 and flange 154) within the chamber 100.

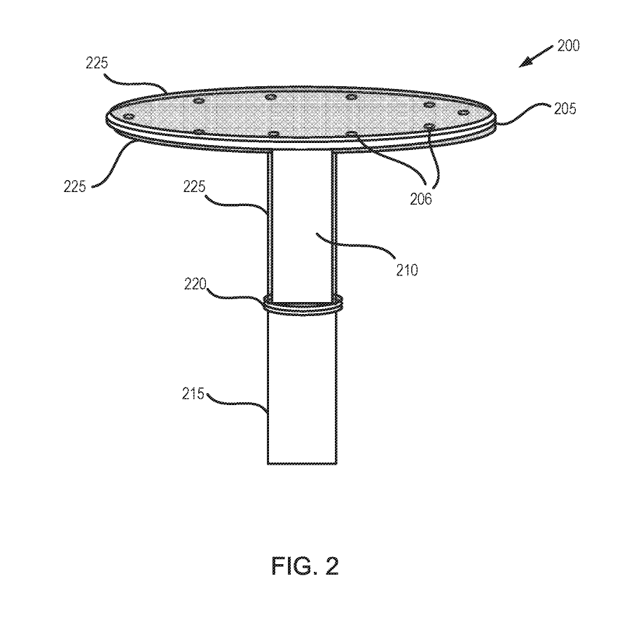

FIG. 2 depicts coated components of a heater assembly 200 in accordance with embodiments. The heater assembly 200 includes a support 205 attached to an end of an interior shaft 210. The interior shaft 210 is situated within the interior volume of the processing chamber (not shown). The interior shaft is attached to an exterior shaft 215 via a flange 220. The support 205 includes mesas 206, which are connected to electrical components (not shown) embedded within the heater material of the support 205. All surfaces that may be exposed to corrosive gases and plasmas within the processing chamber are coated with a low volatile coating 225 in accordance with embodiments described herein.

The low volatile coating 225 may comprise one or more earth metal containing oxide material on a surface of the support 205 and/or on all surfaces of the heater assembly that may be exposed to corrosive gases or plasma within the processing chamber. The low volatile coating may be a single-layer coating having little or no impact on the thermal properties of the heater material of the support 205 or on the performance of the heater generally. The single-layer low volatile coating may have a thickness of about 5 nm to about 10 μm, or about 25 nm to about 5 μm, or about 50 nm to about 500 nm, or about 75 nm to about 200 nm. In some embodiments, the thickness of the single-layer low volatile coating may be about 50 nm, or about 75 nm, or about 100 nm, or about 125 nm, or about 150 nm.

The ALD technique enables a conformal coating of relatively uniform thickness and zero porosity (i.e., porosity-free) on the surfaces of chamber components and on features having complex geometries. The low volatile coating may be plasma resistant to reduce plasma interactions and improving a component's durability without impacting its performance. A thin low volatile coating deposited with ALD may maintain the electrical properties and relative shape and geometric configuration of the component so as to not disturb its functionality. The coating may also reduce the volatility of the component's materials and may form reactants having a lower vapor pressure than the component's underlying materials.

The resistance of the low volatile coating to plasma may be measured through “etch rate” (ER), which may have units of micron/hour (μm/hr) or Angstrom/hour (Å/hr), throughout the duration of the coated components' operation and exposure to plasma. Measurements may be taken after different processing times. For example, measurements may be taken before processing, or at about 50 processing hours, or at about 150 processing hours, or at about 200 processing hours, and so on. Variations in the composition of the low volatile coating grown or deposited on the heater support and/or other components may result in multiple different plasma resistances or erosion rate values. Additionally, a low volatile coating with a single composition exposed to various plasmas could have multiple different plasma resistances or erosion rate values. For example, a plasma resistant material may have a first plasma resistance or erosion rate associated with a first type of plasma and a second plasma resistance or erosion rate associated with a second type of plasma.

In some embodiments, the low volatile coating may comprise an adhesion layer and a second rare-earth metal-containing oxide layer on top of the adhesion layer. The thickness of the adhesion layer may be about 1 nm to about 50 nm, or about 2 nm to about 25 nm, or about 5 nm to about 10 nm. In certain embodiments, the thickness of the adhesion layer is about 1 nm, or about 5 nm, or about 10 nm, or about 15 nm. The thickness of the rare earth metal-containing layer may be about 5 nm to about 10 μm, or about 25 nm to about 5 μm, or about 50 nm to about 500 nm, or about 75 nm to about 200 nm. In some embodiments, the thickness of the single-layer low volatile coating may be about 50 nm, or about 75 nm, or about 100 nm, or about 125 nm, or about 150 nm. In certain embodiments, the total thickness of the low volatile coating including the adhesion layer and the rare earth metal-containing layer may be about 50 nm, or about 75 nm, or about 100 nm, or about 125 nm, or about 150 nm.

In some embodiments, the second rare-earth metal-containing oxide layer may be a stack layer having alternating thin layers of a rare earth metal-containing material and another metal nitride (e.g., an AlN-containing layer) that may function as a stress relief layer. In embodiments, the thickness of the rare earth metal-containing layer in the stack is about 5 ALD cycles (e.g., about 0.9 Å/cycle and two half-reactions) to about 500 nm, or about 6 ALD cycles to about 250 nm, or about 7 ALD cycles to about 100 nm, or about 8 ALD cycles to about 50 nm. In some embodiments, the thickness of the rare earth metal-containing layer in the stack is about 5 to about 15 ALD cycles, or about 6 to about 14 ALD cycles, or about 7 to about 13 ALD cycles, or about 8 to about 10 ALD cycles. The thickness of the metal nitride in the stack may be about 1 to about 10 ALD cycles, or about 2 ALD cycles, or about 5 ALD cycles. In some embodiments, the total thickness of the low volatile coating including the adhesion layer and the stack layer may be about 50 nm to about 5 μm, or about 75 nm to about 1 μm, or about 100 nm to about 500 nm. In certain embodiments, the total thickness of the low volatile coating including the adhesion layer and the rare earth metal-containing layer may be about 50 nm, or about 75 nm, or about 100 nm, or about 125 nm, or about 150 nm.

The adhesion layer may comprise AlN and the rare-earth metal-containing layer may comprise a yttrium oxide, a yttrium fluoride or a yttrium oxyfluoride alone or together with an additional rare earth metal material (e.g., erbium oxide, lanthanum oxide, etc.). The rare earth metal-containing layer may include any rare earth metal-containing material such as those described herein above. Each layer may be coated using an ALD process. The ALD process may grow conformal coating layers of uniform thickness that are thin and porosity-free and that do not substantially affect the electrical properties of the component.

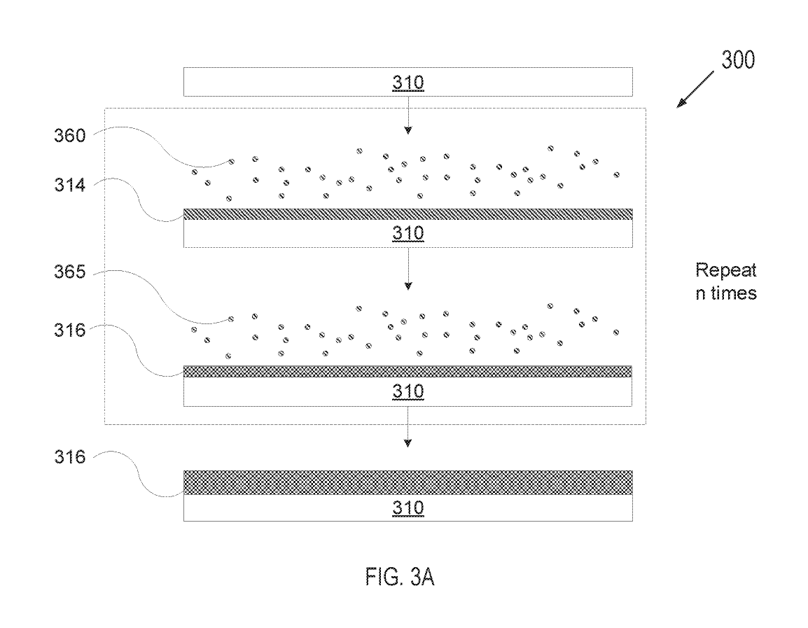

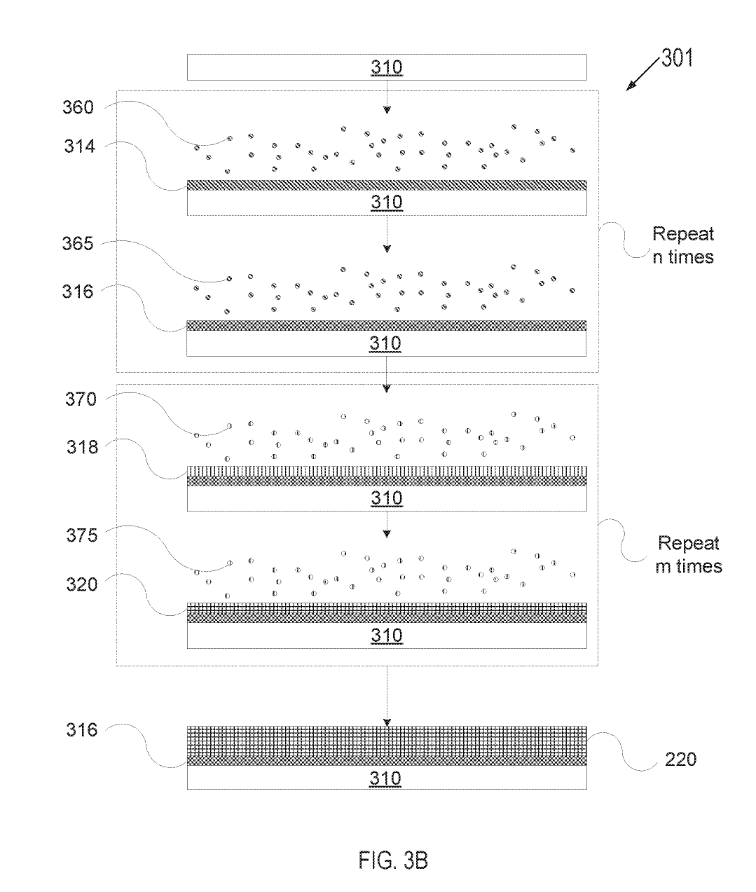

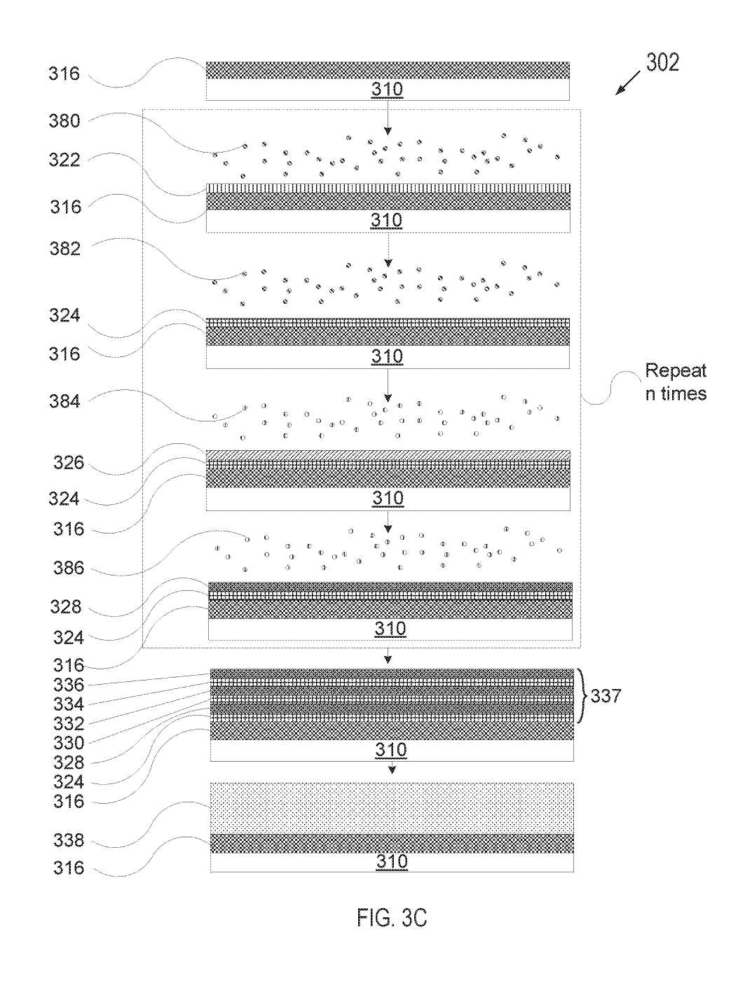

FIG. 3A depicts one embodiment of a deposition process in accordance with an ALD technique to grow or deposit a low volatile coating on an article (e.g., a heater support or entire heater assembly). FIG. 3B depicts one embodiment of a deposition process in accordance with an ALD technique to grow or deposit a multi-layer plasma resistant coating on an article). FIG. 3C depicts another embodiment of a deposition process in accordance with an ALD technique as described herein.

Various types of ALD processes exist and the specific type may be selected based on several factors such as the surface to be coated, the coating material, chemical interaction between the surface and the coating material, etc. The general principle for the various ALD processes comprises growing a thin film layer by repeatedly exposing the surface to be coated to pulses of gaseous chemical precursors that chemically react with the surface one at a time in a self-limiting manner.

FIGS. 3A-3C illustrate an article 310 having a surface. Article 310 may represent various insulator materials of semiconductor process chamber components including but not limited to a high temperature heater support and/or all surfaces of a heater assembly within a processing chamber. The article 310 may be made from a material comprising AlN, a dielectric material such as a ceramic, a metal-ceramic composite (e.g., Al₂O₃/SiO₂, Al₂O₃/MgO/SiO₂, SiC, Si₃N₄, AlN/SiO₂ and the like), a metal (such as aluminum, stainless steel) or other suitable materials, and may further comprise materials such as AlN, Si, SiC, Al₂O₃, SiO₂, and so on. In one embodiment, the article 310 is a high temperature heater comprised of a heater material having a thermal conductivity of about 50 W/mK to about 300 W/mK, or about 100 W/mK to about 250 W/mK, about 150 W/mK to about 200 W/mK, or about 180 W/mK. The heater material may also have a specific heat capacity of about 0.15 cal/g-° C. at 25° C. to about 0.30 cal/g-° C. at 25° C., or about 0.20 cal/g-° C. at 25° C. to about 0.25 cal/g-° C. at 25° C., or about 0.25 cal/g-° C. at 25° C. The heater material may also have a coefficient of linear thermal expansion of about 4.6 to about 5.7 μm/m-° C. In one embodiment, the article 310 is a high temperature heater for a semiconductor process chamber fabricated from an AlN ceramic material.

For ALD, either adsorption of a precursor onto a surface or a reaction of a reactant with the adsorbed precursor may be referred to as a “half-reaction.” During a first half reaction, a precursor is pulsed onto a surface of the article 310 for a period of time sufficient to allow the precursor to fully adsorb onto the surface. The adsorption is self-limiting as the precursor will adsorb onto a finite number of available sites on the surface, forming a uniform continuous adsorption layer on the surface. Any sites that have already adsorbed with a precursor will become unavailable for further adsorption with the same precursor unless and/or until the adsorbed sites are subjected to a treatment that will form new available sites on the uniform continuous coating. Exemplary treatments may be plasma treatment, treatment by exposing the uniform continuous adsorption layer to radicals, or introduction of a different precursor able to react with the most recent uniform continuous layer adsorbed to the surface.

In some embodiments, two or more precursors are injected together and adsorbed onto the surface of an article. The excess precursors are pumped out until an oxygen-containing reactant is injected to react with the adsorbates to form a component layer (e.g., of Y₂O₃—Al₂O₃). This fresh layer is ready to adsorb the precursors in the next cycle.

In FIG. 3A, article 310 may be introduced to a first precursor 360 for a first duration until a surface of article 310 is fully adsorbed with the first precursor 360 to form an adsorption layer 314. Subsequently, article 310 may be introduced to a first reactant 365 to react with the adsorption layer 314 to grow a solid layer 316 (e.g., so that the layer 316 is fully grown or deposited, where the terms grown and deposited may be used interchangeably herein). For a single layer low volatile coating, the first precursor 360 may be a precursor for a rare earth metal-containing material such as Y₂O₃, YF₃ or YₓO_{y}F_{z}. When an adhesion layer is used, the first precursor 360 may be a precursor containing Al. The first reactant 365 may be oxygen, water vapor, ozone, oxygen radicals, or another oxygen source if layer 316 is an oxide. If layer 316 contains AlN, the first reactant 365 may be, for example, NH₃ nitrogen radicals, or other nitrogen source. Accordingly, ALD may be used to form the layer 316. The layer 316 may be a single-layer low volatile coating, or may be one layer (i.e., an adhesion layer) of a multi-layer low volatile coating.

In an example where the layer 316 is an AlN adhesion layer, article 310 (e.g., a surface of a high temperature heater) may be introduced to a first precursor 360 (e.g., a trimethylaluminum or TMA precursor) for a first duration until all the reactive sites on the article's surfaces are consumed. The remaining first precursor 360 is flushed away and then a first reactant 365 of NH₃ is injected into the reactor to start the second half cycle. A layer 316 of AlN forms after NH₃ molecules react with the Al containing adsorption layer created by the first half reaction.

Layer 316 may be uniform, continuous and conformal. Layer 316 may be porosity free (e.g., have a porosity of zero) or have an approximately zero porosity in embodiments (e.g., a porosity of 0% to 0.01%). Layer 316 may have a thickness of less than one atomic layer to a few atoms in some embodiments after a single ALD deposition cycle. Some metalorganic precursor molecules are large. After reacting with the reactant 365, large organic ligands may be gone, leaving much smaller metal atoms. One full ALD cycle (e.g., that includes introduction of precursors 360 followed by introduction of reactants 365) may result in the formation of a layer with an average thickness less than a single unit cell. For example, an AlN monolayer grown by TMA and NH₃ typically has a growth rate of about 1.0 A/cycle while the AlN lattice constants are a=3.111A and c=4.981A (for a hexagonal structure).

Multiple full ALD deposition cycles may be implemented to deposit a thicker layer 316, with each full cycle (e.g., including introducing precursor 360, flushing, introducing reactant 365, and again flushing) adding to the thickness by an additional fraction of an atom to a few atoms. As shown, up to n full cycles may be performed to grow the layer 316, where n is an integer value greater than 1. In embodiments, layer 316 may have a thickness of about 5 nm to about 10 μm, or about 25 nm to about 5 μm, or about 50 nm to about 500 nm, or about 75 nm to about 200 nm. In some embodiments, the thickness of the low volatile coating may be about 50 nm, or about 75 nm, or about 100 nm, or about 125 nm, or about 150 nm. If layer 316 is an adhesion layer, the thickness of the adhesion layer may be about 1 nm to about 50 nm, or about 2 nm to about 25 nm, or about 5 nm to about 10 nm. In certain embodiments, the thickness of the adhesion layer is about 1 nm, or about 5 nm, or about 10 nm, or about 15 nm.

When layer 316 is a low volatile coating comprising one or more rare earth metal-containing materials, the layer 316 provides robust plasma resistance and mechanical properties without significantly impacting the thermal and electrical properties of the heater. Layer 316 may protect the component from erosion, enhance or maintain dielectric strength and may be resistant to cracking at temperatures up to about 500° C., or up to about 550° C., or from about 500° C. to about 550° C. When layer 316 is an adhesion layer, it may improve adhesion of a rare earth metal-containing layer (or a stack layer) to the component and prevent cracking of the low volatile coating at temperatures of up to about 650° C.

FIG. 3B describes a deposition process 301 that includes the deposition of layer 316 as an adhesion layer as described with reference to FIG. 3A. However, the deposition process 301 of FIG. 3B further includes deposition of an additional layer 320 to form a multi-layer plasma resistant coating. Accordingly, after layer 316 is complete, article 310 having layer 316 may be introduced to an additional one or more precursors 370 for a second duration until layer 316 is fully adsorbed with the one or more additional precursors 370 to form an adsorption layer 318. Subsequently, article 310 may be introduced to a reactant 375 to react with adsorption layer 318 to grow a solid rare-earth metal-containing oxide layer 320, also referred to as the second layer 320 for simplicity (e.g., so that the second layer 320 is fully grown or deposited). In this embodiment, layer 316 may be an adhesion layer containing AlN. Accordingly, the second layer 320 is fully grown or deposited over layer 316 using ALD. In an example, precursor 370 may be a yttrium containing precursor used in the first half cycle, and reactant 375 may be H₂O used in the second half cycle.

The second layer 320 may form a yttrium-containing oxide layer or other rare-earth metal-containing oxide layer, which may be uniform, continuous and conformal. The second layer 320 may have a very low porosity of less than 1% in embodiments, and less than 0.1% in further embodiments, and about 0% in embodiments or porosity-free in still further embodiments. Second layer 220 may have a thickness of less than an atom to a few atoms (e.g., 2-3 atoms) after a single full ALD deposition cycle. Multiple ALD deposition stages may be implemented to deposit a thicker second layer 320, with each stage adding to the thickness by an additional fraction of an atom to a few atoms. As shown, the full deposition cycle may be repeated m times to cause the second layer 320 to have a target thickness, where m is an integer value greater than 1. In embodiments, second layer 320 may have a thickness of about 5 ALD cycles (e.g., about 0.9 Å/cycle and two half-reactions) to about 5 μm. If second layer 320 is the first layer of a stack layer, then it may have a thickness of about 5 ALD cycles to about 500 nm, or about 6 ALD cycles to about 250 nm, or about 7 ALD cycles to about 100 nm, or about 8 ALD cycles to about 50 nm. In embodiments, the thickness of the second layer 320 of the stack is about 5 to about 15 ALD cycles, or about 6 to about 14 ALD cycles, or about 7 to about 13 ALD cycles, or about 8 to about 10 ALD cycles.

A ratio of the second layer 320 thickness to the layer 316 thickness may be 200:1 to 1:200. A higher ratio of the second layer 320 thickness to the layer 316 thickness (e.g., 200:1, 100:1, 50:1, 20:1, 10:1, 5:1, 2:1 etc.) provides better corrosion and erosion resistance, while a lower ratio of the second layer 320 thickness to the layer 316 thickness (e.g., 1:2, 1:5, 1:10, 1:20, 1:50, 1:100, 1:200) provides better heat resistance (e.g., improved resistance to cracking and/or delamination caused by thermal cycling).

Second layer 320 may be any of the aforementioned rare-earth metal-containing oxide layers. For example, second layer 320 may be Y₂O₃, YF₃ or YₓO_{y}F_{z}, alone or in combination with one or more other rare earth metal materials. In some embodiments, second layer 320 is a single phase material formed from a mixture of at least two rare earth metal-containing precursors that have been co-deposited by ALD (e.g., combinations of one or more of Y₂O₃, Er₂O₃ and Al₂O₃). For example, second layer 320 may be one of YₓEr_{y}O_{z}or YₓAl_{y}O_{z}. In one embodiment, layer 316 is amorphous AlN and the second layer 320 is a polycrystalline or amorphous yttrium-containing oxide compound (e.g., Y₂O₃, YₓAl_{y}O_{z}, YₓEr_{y}O_{z}) alone or in a single phase with one or more other rare earth metal-containing material. Layer 316 may not only enhance adhesion, but may also function as a stress relief layer that is deposited prior to deposition of the yttrium-containing oxide layer.

In some embodiments, second layer 320 may include Er₂O₃, Y₂O₃ or Al₂O₃. In some embodiments, second layer 320 is a multi-component material of at least one of ErₓAl_{y}O_{z} (e.g., Er₃Al₅O₁₂), YₓAl_{y}O_{z}, YₓEr_{y}O_{z}, or ErₐYₓAl_{y}O_{z} (e.g., a single phase solid solution of Y₂O₃, Al₂O₃ and Er₂O₃).

With reference to FIG. 3C, in some embodiments, the multi-layer low volatile coating contains more than two layers. Specifically, the low volatile coating may include a stack layer comprising a sequence of alternating layers of an AlN layer and the rare-earth metal-containing oxide layer, or may include layer 316 and a sequence of alternating layers for the rare-earth metal-containing oxide layer. In some embodiments, a rare-earth metal-containing oxide layer is a layer of alternating sub-layers. For example, a rare-earth metal-containing oxide layer may be a series of alternating sublayers of Y₂O₃ and AlN or a series of alternating sublayers of Y₂O₃ and Al₂O₃.

Referring to FIG. 3C, an article 310 having a layer 316 may be inserted into a deposition chamber. The layer 316 may have been formed as set forth with reference to FIG. 3A or FIG. 3B. Article 310 may be introduced to one or more precursors 380 containing one or more rare earth metal-containing materials for a duration until layer 316 is fully adsorbed with the one or more precursors 380 to form layer 322. Subsequently, article 310 may be introduced to a reactant 382 to react with layer 322 to grow layer 324. Accordingly, the rare earth metal-containing layer 324 is fully grown or deposited over layer 316 using ALD. In an example, precursor 380 may be a yttrium containing precursor used in the first half cycle, and reactant 382 may be H₂O used in the second half cycle. The rare earth metal-containing layer 324 may be a first one of Y₂O₃, Er₂O₃ or another oxide.

Article 310 having layer 316 and metal oxide layer 324 may be introduced to one or more precursors 384 for a duration until an AlN layer 324 is fully adsorbed with the one or more precursors 384 to form layer 326. Subsequently, article 310 may be introduced to a reactant 386 to react with layer 326 to grow an additional AlN layer 328. Accordingly, the additional AlN layer 328 is fully grown or deposited over the rare earth metal-containing layer 324 using ALD. In an example, precursor 384 may be an AlN containing precursor used in the first half cycle, and reactant 386 may be NH₃ used in the second half cycle.

As shown, the deposition of the rare earth metal-containing layer 324 and the aluminum oxide layer 328 may be repeated n times to form a stack 337 of alternating layers, where n is an integer value greater than 2. N may represent a finite number of layers selected based on the targeted thickness and properties. The stack 337 of alternating layers may be considered as a rare-earth metal-containing oxide layer containing multiple alternating sub-layers. Accordingly, precursors 380, reactants 384, precursors 384 and reactants 386 may be repeatedly introduced sequentially to grow or deposit additional alternating layers 330, 332, 334, 336, and so on. Each of the layers 324, 324, 330, 332, 334, 336, and so on may be very thin layers having an average thickness of less than a single atomic layer to a few atomic layers.

The alternating layers 324-336 described above have a 1:1 ratio, where there is a single layer of a first metal oxide for each single layer of AlN. However, in other embodiments there may be other ratios such as 2:1, 3:1, 4:1, and so on between the different types of layers. For example, two Y₂O₃ layers may be deposited for every AlN layer in an embodiment. Additionally, the stack 337 of alternating layers 324-336 has been described as an alternating series of two types of metal layers. However, in other embodiments more than two types of metal layers may be deposited in an alternating stack 337. For example, the stack 337 may include three different alternating layers (e.g., a first layer of Y₂O₃, a first layer of AlN, a first layer of Al₂O₃, a second layer of Y₂O₃, a second layer of AlN, a second layer of Al₂O₃, and so on).

After the stack 337 of alternating layers has been formed, an anneal process may be performed to cause the alternating layers of different materials to diffuse into one another and form a complex oxide having a single phase or multiple phases. After the annealing process, the stack of alternating layers 337 may therefore become a single rare-earth metal-containing oxide layer 338. For example, if the layers in the stack are Y₂O₃ and Al₂O₃, then the resulting rare-earth metal-containing oxide layer 338 may consist of the Y₃Al₅O₁₂ (YAG) phase.

Each layer of the rare earth metal-containing material may have a thickness of about 5-10 angstroms and may be formed by performing about 1 to about 10 cycles of an ALD process, where each cycle forms a nanolayer (or slightly less or more than a nanolayer) of the rare earth metal-containing material. In one embodiment, each layer of the rare-earth metal-containing oxide is formed using about 6 to about 8 ALD cycles. Each AlN layer may be formed from about 1 to about 2 ALD cycles (or a few ALD cycles) and may have a thickness of less than an atom to a few atoms. Layers of the rare earth metal-containing material may each have a thickness of about 5-100 angstroms, and layers of the second oxide may each have a thickness of about 1-20 angstroms in embodiments, and a thickness of 1-4 angstroms in further embodiments. The stack 337 of alternating layers of the rare earth metal-containing material and the AlN may have a total thickness of about 5 nm to about 3 μm. The thin layers of the AlN between the layers of the rare earth metal-containing material may prevent crystal formation in the rare earth metal-containing layers. This may enable an amorphous yttria layer to be grown.

In the embodiments described with reference to FIGS. 3A-3C, the surface reactions (e.g., half-reactions) are done sequentially, and the various precursors and reactants are not in contact in embodiments. Prior to introduction of a new precursor or reactant, the chamber in which the ALD process takes place may be purged with an inert carrier gas (such as nitrogen or air) to remove any unreacted precursor and/or surface-precursor reaction byproducts. The precursors will be different for each layer and the second precursor for the yttrium-containing oxide layer or other rare-earth metal-containing oxide layer may be a mixture of two rare earth metal-containing precursors to facilitate co-deposition of these compounds to form a single phase material layer. In some embodiments, at least two precursors are used, in other embodiments at least three precursors are used and in yet further embodiments at least four precursors are used.

ALD processes may be conducted at various temperatures depending on the type of process. The optimal temperature range for a particular ALD process is referred to as the “ALD temperature window.” Temperatures below the ALD temperature window may result in poor growth rates and non-ALD type deposition. Temperatures above the ALD temperature window may result in reactions taken place via a chemical vapor deposition (CVD) mechanism. The ALD temperature window may range from about 100° C. to about 650° C. In some embodiments, the ALD temperature window is from about 20° C. to about 200° C., or about 25° C. to about 150° C., or about 100° C. to about 120° C., or about 20° C. to 125° C.

The ALD process allows for a conformal low volatile coating having uniform thickness on articles and surfaces having complex geometric shapes, holes with high aspect ratios (e.g., pores), and three-dimensional structures. Sufficient exposure time of each precursor to the surface enables the precursor to disperse and fully react with the surfaces in their entirety, including all of its three-dimensional complex features. The exposure time utilized to obtain conformal ALD in high aspect ratio structures is proportionate to the square of the aspect ratio and can be predicted using modeling techniques. Additionally, the ALD technique is advantageous over other commonly used coating techniques because it allows in-situ on demand material synthesis of a particular composition or formulation without a lengthy and difficult fabrication of source materials (such as powder feedstock and sintered targets). In some embodiments ALD is used to coat articles having aspect ratios of about 3:1 to 300:1.

With the ALD techniques described herein, multi-component films such as YₓAl_{y}O_{z} (e.g., Y₃Al₅O₁₂), YₓEr_{y}O_{z}, YₓEr_{y}F_{z}, or Y_{w}ErₓO_{y}F_{z} can be grown, deposited or co-deposited, for example, by proper mixtures of the precursors used to grow the rare-earth metal-containing oxides alone or in combination with one or more other oxides as described above and in more detail in the examples below.

In some embodiments a wear resistant layer containingone or more rare earth metal-containing materials may be deposited over the stack layer. The wear resistant layer may have a thickness of about 5 nm to about 1000 nm, or about 100 nm to about 500 nm.

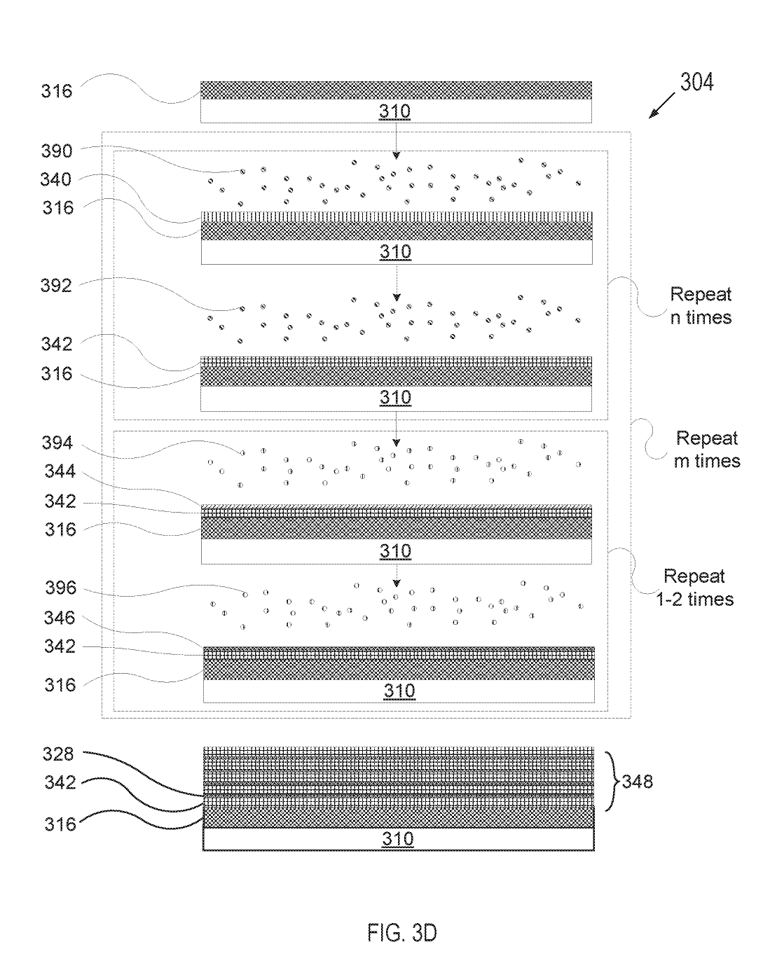

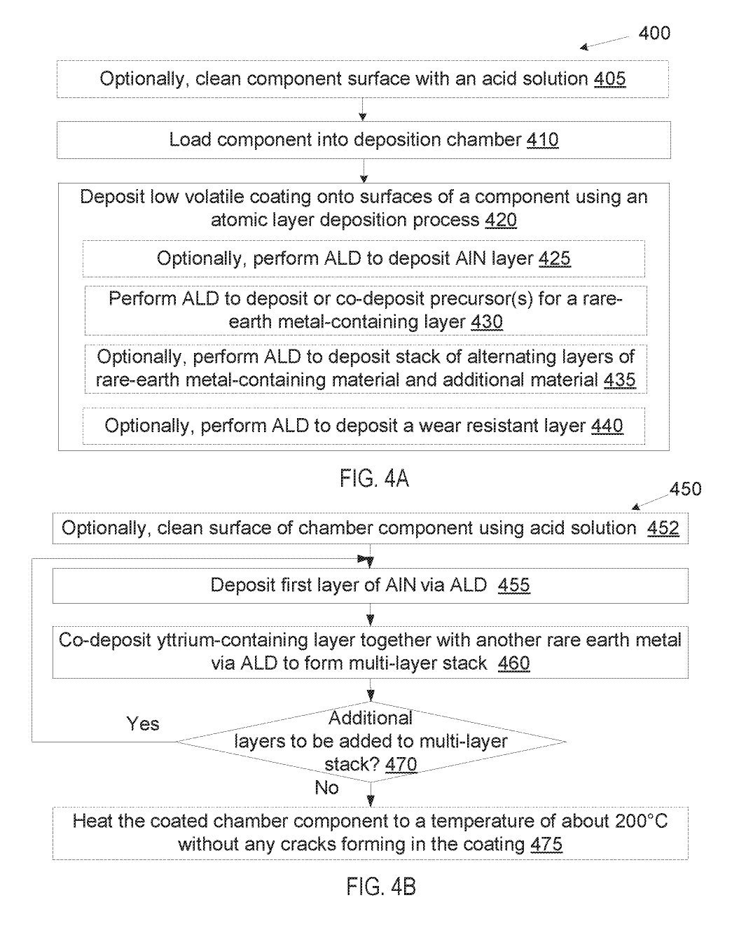

FIG. 4A illustrates a method 400 for forming a low volatile coating on a process chamber component (e.g., a surface or all surfaces of a high temperature heater) according to embodiments. Method 400 may be used to coat any articles described herein. The method may optionally begin by selecting a composition for the low volatile coating. The composition selection and method of forming may be performed by the same entity or by multiple entities.

The method may optionally include, at block 405, cleaning the article with an acid solution. In one embodiment, the article is bathed in a bath of the acid solution. The acid solution may be a hydrofluoric acid (HF) solution, a hydrochloric acid (HCl) solution, a nitric acid (HNO₃) solution, or combination thereof in embodiments. The acid solution may remove surface contaminants from the article and/or may remove an oxide from the surface of the article. Cleaning the article with the acid solution may improve a quality of a coating deposited using ALD. In one embodiment, an acid solution containing about 0.1 vol % to about 5.0 vol % HF is used to clean chamber components made of quartz. In one embodiment, an acid solution containing about 0.1 vol % to about 20 vol % HCl is used to clean articles made of Al₂O₃. In one embodiment, an acid solution containing about 5 to about 15 vol % HNO₃ is used to clean articles made of aluminum and other metals.

At block 410, the article is loaded into an ALD deposition chamber. At block 420, the method comprises depositing a low volatile coating onto a surface of the article using ALD. In one embodiment, optionally at block 425 ALD is performed to deposit an adhesion layer such as an AlN layer. In one embodiment, at block 430 ALD is performed to deposit or co-deposit a rare-earth metal-containing oxide layer alone or together with one or more other oxides. ALD is a very conformal process as performed in embodiments, which may cause the surface roughness of the low volatile coating to match a surface roughness of an underlying surface of the article that is coated. The low volatile coating may have a total thickness of about 5 nm to about 3 μm in some embodiments. The low volatile coating may have a porosity of about 0% in embodiments, or may be porosity-free in embodiments, and may have a thickness variation of about ±5% or less, ±10% or less, or ±20% or less. The dielectric constant of the article with the low volatile coating may be the same or substantially the same (e.g., within ±5%) of the dielectric constant of the article without the coating. Additionally, if the article is a high temperature heater, the maximum temperature, thermal conductivity and specific heat capacity of the heater may be same or substantially the same (e.g., within ±5%) of the maximum temperature, thermal conductivity and specific heat capacity of the heater without the coating.

In one embodiment, optionally, at block 435 ALD is performed to deposit a stack of alternating layers of a rare-earth metal containing oxide and AlN. In further embodiment, optionally at block 440 ALD is performed to deposit a wear resistant layer on the stack.

A yttrium-containing oxide layer includes a yttrium-containing oxide and may include one or more additional rare earth metal materials. Rare earth metal-containing materials that include yttrium may be used to form the low volatile coating in embodiments because yttrium-containing oxides generally have high stability, high hardness, superior erosion resistant properties and form relatively low vapor pressure reactants with fluorine plasmas (e.g., NF₃). For example, Y₂O₃ is one of the most stable oxides and has a standard Gibbs free energy of formation (ÅG_{f}°) of −1816.65 kJ/mol, indicating the reactions of Y₂O₃ with most of the process chemicals are thermodynamically unfavorable under standard conditions. Low volatile coatings that include an AlN adhesion layer and rare-earth metal-containing oxide layer with Y₂O₃ deposited in accordance with embodiments herein may also have a low erosion rate to many plasma and chemistry environments, such as an erosion rate of about 0 μm/hr when exposed to a direct NF₃ plasma chemistry at a bias of 200 Watts and 500° C. Examples of yttrium-containing oxide compounds that the plasma resistant coating may be formed of include Y₂O₃, YₓAl_{y}O_{z}, (e.g., Y₃Al₅O₁₂) or YₓEr_{y}O_{z}. The yttrium content in the plasma resistant coating may range from about 0.1 at. % to close to 100 at. %. For yttrium-containing oxides, the yttrium content may range from about 0.1 at. % to close to 100 at. % and the oxygen content may range from about 0.1 at. % to close to 100 at. %.

Examples of erbium-containing oxide compounds that the plasma resistant coating may be formed of include Er₂O₃, ErₓAl_{y}O_{z} (e.g., Er₃Al₅O₁₂) and YₓEr_{y}O_{z}. The erbium content in the plasma resistant coating may range from about 0.1 at. % to close to 100 at. %. For erbium-containing oxides, the erbium content may range from about 0.1 at. % to close to 100 at. % and the oxygen content may range from about 0.1 at. % to close to 100 at. %.

In embodiments, a low volatile coating that includes the adhesion layer and the rare-earth metal-containing oxide layer of Y₂O₃, YₓAl_{y}O_{z} (e.g., Y₃Al₅O₁₂) or YₓEr_{y}O_{z} has a low outgassing rate, a dielectric breakdown voltage on the order of about 1000 V/μm, a hermiticity (leak rate) of less than about 1E-8 Torr/s, a Vickers hardness of about 600 to about 950 or about 685, an adhesion of about 75 mN to about 100 mN or about 85 mN as measured by the scratch test and a film stress of about −1000 to −2000 MPa (e.g., about −1140 MPa) as measured by x-ray diffraction at room temperature.

In some embodiments, the adhesion layer of the low volatile coating may be formed by ALD from an aluminum-containing precursor such as trimethylaluminum and a nitrogen-containing reactant such as ammonia (NH₃), plasma activated ammonia, hydrazine (N₂H₄), nitrogen gas (N₂), plasma-activated nitrogen gas and nitric oxide (NO). In some embodiments, the rare earth metal-containing layer of the low volatile coating is or includes yttria, and the yttrium precursor used to form the rare-earth metal-containing oxide layer via ALD may be selected from or include tris(N,N-bis(trimethylsilyl)amide)yttrium (III) or yttrium (III)butoxide and the reactant may be selected from O₂, H₂O or O₃.

In some embodiments, the low volatile coating may further include an erbium oxide. For ALD, an erbium precursor may be selected from tris-methylcyclopentadienyl erbium(III) (Er(MeCp)₃), erbium boranamide (Er(BA)₃), Er(TMHD)₃, erbium(III)tris(2,2,6,6-tetramethyl-3,5-heptanedionate), or tris(butylcyclopentadienyl)erbium(III) and the reactant may be selected from O₂, H₂O or O₃.

FIG. 4B illustrates a method 450 for forming a low volatile coating on an article (e.g., a high temperature heater) according to an embodiment. The method may optionally begin by selecting compositions for the low volatile coating. The composition selection and method of forming may be performed by the same entity or by multiple entities.

At block 452 of method 450, a surface of the article is cleaned using an acid solution. The acid solution may be any of the acid solutions described above with reference to block 405 of method 400. The article may then be loaded into an ALD deposition chamber.

Pursuant to block 455, the method comprises depositing a first layer of amorphous AlN onto at least one surface of the article via ALD. The amorphous AlN may have a thickness of about 5 nm to about 300 nm. Pursuant to block 460, the method further comprises forming a second layer by co-depositing (i.e., in one step) a mixture of a yttrium-containing oxide precursor and another oxide precursor onto the AlN adhesion layer via ALD. The second layer may include Y₂O₃ in a single phase with Al₂O₃ or Er₂O₃, for example. Alternatively, the second layer may include multiple phases, such as a phase of Y₂O₃ and Er₂O₃.

As discussed above, the rare-earth metal-containing oxide layer may include a mixture of multiple different oxides. To form such a rare-earth metal-containing oxide layer, any combination of the aforementioned yttria precursors, erbium oxide precursors, and alumina precursors together with appropriate reactants, may be introduced together into an ALD deposition chamber to co-deposit the various oxides and form a layer having a single phase or multiple phases.

At block 470, a determination may be made as to whether additional layers are to be added (e.g., if a multi-layer stack is to be formed). If additional layers are to be added, then the method may return to block 455 and an additional layer of AlN may be formed. Otherwise the method may proceed to block 475.

At block 475, the article (e.g., the insulator plate, ceramic electrostatic puck, ESC assembly, etc.) and both layers of the low volatile coating on the chamber component are heated. The heating may be via an annealing process, a thermal cycling process and/or via a manufacturing step during semiconductor processing. In one embodiment, the thermal cycling process is performed on coupons as a check after manufacture to detect cracks for quality control, where the coupons are cycled to the highest temperature that a part may experience during processing. The thermal cycling temperature depends on a specific application or applications that the part will be used for. The temperature may be selected based on the material of construction of the article, surface, and film layers so as to maintain their integrity and refrain from deforming, decomposing, or melting any or all of these components.

Methods 400 and 450 may be performed on a single component or on a batch of multiple components. The multiple components may be the same type of component or may be different types of components. Methods 400 and 450 may also be performed on assembled high temperature heater assemblies (or portions thereof).

The following examples are set forth to assist in understanding the embodiments described herein and should not be construed as specifically limiting the embodiments described and claimed herein. Such variations, including the substitution of all equivalents now known or later developed, which would be within the purview of those skilled in the art, and changes in formulation or minor changes in experimental design, are to be considered to fall within the scope of the embodiments incorporated herein. These examples may be achieved by performing method 300 or method 350 described above.

### EXAMPLES

### Example 1

### Deposition of Lanthanum Oxide on Glass and Silicon Substrates Using ALD

A lanthanum oxide layer was deposited on glass and silicon substrates using atomic layer deposition. Lanthanum silylamide, La[N(SiMe₃)₂]₃ and water were used as the precursors and the deposition occurred at a temperature range of 150° C. to 250° C. The effect of pulse times, precursor evaporation temperature on the growth rate and refractive index was investigated. The resulting La₂O₃ films contained noticeable amounts of hydrogen and silicon and were chemically unstable while stored in ambient air. The La₂O₃ films were achieved with stoichiometry close to that of LaAlO₃ at 225° C. from La[N(SiMe₃)₂]₃, Al(CH₃)₃, and H₂O. The lanthanum β-diketonate precursor, La(thd)₃, was used as a reference precursor.

### Example 2

### Yttrium Oxide Coatings Deposited by ALD on AlN Substrates

A yttrium oxide coating was deposited by atomic layer deposition, in accordance with methods described herein, on an AlN ceramic substrate. The yttrium oxide coating had a thickness of about 2 μm. As confirmed by transmission electron microscopy and electron diffraction, the yttrium oxide coating had a polycrystalline structure. A reacted layer was formed between the yttrium oxide coating and the AlN substrate.

### Example 3

### Yttrium Fluoride Coating on an Aluminum Nitride Ceramic Substrate

A yttrium fluoride coating was deposited by atomic layer deposition, in accordance with methods described herein, on an aluminum nitride ceramic substrate. The yttrium fluoride coating had a thickness of about 160 nm. As confirmed by transmission electron microscopy and electron diffraction, the yttrium fluoride coating had a polycrystalline structure. A reacted layer was formed between the yttrium oxide coating and the aluminum nitride substrate.

### Example 4

### Prophetic Example—Deposition of a Low Volatile Coating on a Heater

According to embodiments, low volatile coatings as described herein can include a barrier layer that can be deposited by ALD over the entire surface of an AlN substrate (e.g., a heater material). The barrier layer can include a rare earth metal containing oxide top layer and a stress management layer. The rare earth metal containing oxide top layer can have a thickness of about 50 nm to about 5 μm, or about 75 nm to about 3 μm, or about 100 nm to about 2 μm. In embodiments, the top layer can be a rare earth metal containing oxide, for example, Y₂O₃, La₂O₃, Er₂O₃, Lu₂O₃, Sc₂O₃, Gd₂O₃, Sm₂O₃, Dy₂O₃, ternary variants thereof, and combinations thereof.

As discussed above, the barrier layer can also include a stress management layer underlying the top layer. The stress management layer can include an AlN adhesion layer (about 10 nm) deposited by ALD on the surface of the AlN substrate. Over the adhesion layer, a rare earth metal containing oxide layer can be deposited by ALD using about 5 to about 15, or about 8 to about 10 deposition cycles. In some embodiments, the stress management layer can include about two to about four cycles of AlN on top of the rare earth metal containing oxide layer.

The barrier layer can have a coefficient of thermal expansion (CTE) similar to that for AlN (i.e., about 4.6 μm/m-° C. to about 5.7 μm/m-° C.). In embodiments, the coefficient of thermal expansion for the barrier layer material can be about 3.0 μm/m-° C. to about 20.0 μm/m-° C., or about 5.0 μm/m-° C. to about 15.0 μm/m-° C., or about 5.0 μm/m-° C., or about 10.0 μm/m-° C., or about 14.0 μm/m-° C. In embodiments, the CTE of the barrier layer material can be within +/−20%, or +/−10%, or +/−5%, or +/−2% of the CTE of the AlN heater material. The barrier layer can be resistant to fluorine and can contribute little or no metal contamination. To the extent that the barrier layer reacts with fluorine plasma, the resulting metal fluoride gases (MFₓ) can have a low vapor pressure.

A wear-resistant layer can be deposited over the barrier layer. The wear-resistant layer can have a thickness of about 100 nm to about 5 μm, or about 250 nm to about 2 μm, or about 500 nm to about 1 μm. According to embodiments, the wear resistant layer can be a rare earth metal containing layer, for example, Y₂O₃, Er₃Al₅O₁₂ (EAG), Er₂O₃, La₂O₃ and combinations thereof.

The wear-resistant layer can be resistant to fluorine and, to the extent that the wear-resistant layer reacts with fluorine plasma, the resulting metal fluoride gases (MFₓ) can have a low vapor pressure. According to embodiments, the wear resistant layer can have a hardness similar to the hardness of the underlying AlN substrate (i.e., about 10.4 GPa). For example, the hardness of the wear-resistant layer can be about 5.0 GPa to about 15 GPa, or about 7.5 GPa to about 14 GPa, or about 10 GPa to about 13.8 GPa. The wear-resistant layer can have a CTE similar to that for AlN (i.e., about 4.6 μm/m-° C. to about 5.7 μm/m-° C.) and/or to the CTE of the barrier layer. In embodiments, the coefficient of thermal expansion for the wear-resistant layer can be about 3.0 μm/m-° C. to about 20.0 μm/m-° C., or about 5.0 μm/m-° C. to about 15.0 μm/m-° C., or about 5.0 μm/m-° C., or about 10.0 μm/m-° C., or about 14.0 μm/m-° C.

According to embodiments, the barrier layer and the wear-resistant layer can be deposited by methods other than ALD, for example, by chemical vapor deposition (CVD), electron beam ion assisted deposition (IAD), ion plating, sputtering and plasma enhanced CVD (PECVD).

### Example 5

### Prophetic Example—Multilayer Y₂O₃/AlN Coating on an AlN Heater

According to embodiments described herein, low volatile coatings formed of nanolaminated rare earth oxide (REO) and aluminum nitride layers can be deposited on AlN substrates. An AlN adhesion layer having a thickness of about 1 nm to about 10 nm can be first deposited on the AlN substrate. The interface between the AlN adhesion layer and the AlN heater material can be an AlON. Thereafter, a stack of alternating layers (also referred to as a wear resistant layer) of about 8 nm to about 10 nm of a rare earth oxide (REO) and about 2 nm AlN can be deposited to build up a 100 nm REO/AlN alternating layer. For example, alternating layers of about 8 to 10 deposition cycles of Y₂O₃ and two (2) deposition cycles of AlN can be deposited by ALD. In some embodiments, the top layer of the stack is a REO, for example, Y₂O₃, Er₂O₃, Gd₂O₃ or a combination thereof.

In embodiments, a plasma resistant layer can be deposited on the stack of alternating layers. The plasma resistant layer can include Y₂O₃, Er₂O₃, Gd₂O₃ and combinations thereof. The plasma resistant layer can have a thickness of about 100 nm to about 5 μm, or about 250 nm to about 2.5 μm, or about 500 nm to about 1 μm. In embodiments, the heater substrate may include a mesa (dimple) with a Ra of 16 μin and the heater top surface may have a Ra of 40 μin (bead blast).

Thermal stress modeling of a multilayer REO/AlN coating on an AlN heater where the rare earth metal containing oxide layers include Y₂O₃ and Er₂O₃ was performed. Table 1 provides the results.

TABLE 1
Thermal stress modeling of a multilayer REO/AlN coating
on an AlN heater

| | | Coefficient of | | |
|---|---|---|---|---|
| | Young's | Thermal | | |
| Coating | Modulus, | Expansion, CTE × | Hardness | |
| Candidates | E (GPa) | 10\hat{ }6 | (GPa) | CTE Note |
| AlN | 300 | 5.7 | 10.4 | RT-1000° C. |
| Y₂O₃ | 180 | 7.6 | 6 | TR-800° C. |
| Er₂O₃ | 177 | 7.3 | 13.8 | 633° C. |

### Example 6

### Thermal Stress Analysis of Y₂O₃ Coating on an AlN Substrate

Yttrium oxide coatings were deposited by ALD onto AlN substrates. One of the samples had a Y₂O₃ coating with a thickness of 500 nm and another sample had a Y₂O₃ coating with a thickness of 5 μm. The thickness of the AlN substrates were 5 mm. The samples were heated in a process chamber to a temperature of 650° C. The results are set forth in Table 2.

TABLE 2
Thermal Stress Results

| | | Tensile Stress | | Compressive Stress | | Shear Stress | |
|---|---|---|---|---|---|---|---|
| Y₂O₃ | | (MPa) | | (MPa) | | (MPa) | |
| Thickness | | Max. | Avg. | Max. | Avg. | Max. | Avg. |
| 500 | nm | 17 | 0 | −363 | −348 | 175 | 174 |
| 5 | μm | 22 | 0 | −566 | −348 | 192 | 174 |

The stresses in the coating layer were compressive dominant because the CTE of the coating is higher than that of the AlN substrate. Except for edge effects, there was no significant difference in thermal stress results between the two thicknesses of the Y₂O₃ coatings.

Certain assumptions may be made in modeling the properties of the 500 nm and 5 μm thick Y₂O₃ coatings on the AlN nitride substrates: 1) the coating layer can be modeled only on the top side of the substrate; 2) the material properties of all parts are assumed to be the same at all temperatures; temperature dependent properties are not applied; 3) temperature along the radius of the substrate and coating layers is assumed to be the same without any gradient—temperature uniformity is not modeled; and 4) perfectly bonded contact is applied at the interface of the substrate and coating layers.

The material properties of the substrate and Y₂O₃ and AlN layers set forth in Table 3.

TABLE 3
Material Properties

| | | Young's | | |
|---|---|---|---|---|
| | | Modulus | | |
| Part | Material | (GPa) | Poisson's Ratio | CTE (/K) |
| Substrate | AlN | 300 | 0.177 | 5.7e−6 |
| Coating Layer 1 | Y₂O₃ | 150 | 0.298 | 8e−6 |
| Coating Layer 2 | AlN | 215 | 0.177 | 5.2e−6 |

Based on the thermal stress properties and the material properties, the theoretical stress value in a coating layer having two layers (i.e., a 5 mm AlN substrate and Y₂O₃ at 100 nm) and a mismatch in CTE's is −308.6 MPa (i.e., compressive stress) as calculated by Microsoft Excel's CAE tool.

### Example 7

### Erbium Oxide Coatings Deposited by Various Techniques

Erbium oxide was deposited on substrates using radio frequency (RF) sputtering, electron beam evaporation, metal-organic chemical vapor deposition (MOCVD) and atomic layer deposition (ALD). Organometallic tris(methylcyclopentadienyl)erbium and water were used as precursors for the atomic layer deposition of Er₂O₃ thin films on Si(100) and soda-lime glass substrates. The deposition occurred at a temperature of range of 175° C. to 450° C. The ALD growth-type mechanism was confirmed at relatively low deposition temperatures of 250° C. and 300° C. where a high growth rate (i.e., 1.5 A/cycle) was achieved. The deposited Er₂O₃ films were smooth and very uniform and contained only low concentrations of carbon and hydrogen impurities. The films were crystalline with the (111) orientation of the cubic phase dominating. The effective permittivity of the Er₂O₃/native SiO₂-insulator stack was about 10.

### Example 8

### AlN Deposition by ALD

An AlN thin film was grown by plasma enhanced atomic layer deposition using trimethylaluminum and ammonia precursors. A method was developed to provide a crystalline thin film AlN with almost zero thickness variation and a one layer deposition of atoms per each cycle of the process. The growth rate was saturated at about 1 Å/cycle, and the thickness was proportional to the number of reaction cycles. The preferred crystal orientation, uniformity of the nucleation and the surface roughness of the grown AlN were investigated. X-ray diffraction (XRD), atomic focused microscopy (AFM) and scanning electron microscopy (SEM) were carried out to analyze the crystallinity and properties of the films.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. An article comprising:
a component comprising a heater material with a thermal conductivity of about 50 W/mK to about 300 W/mK; and
a low volatile coating on a surface of the heater material, the low volatile coating having a thickness of about 5 nm to about 5 μm,
wherein the low volatile coating comprises a rare earth metal-containing material, and
wherein the heater material with the low volatile coating has the thermal conductivity or an adjusted thermal conductivity that is within about ±5% of the thermal conductivity of the heater material without the low volatile coating.

2. The article of claim 1, wherein the article is a high temperature heater.

3. The article of claim 1, wherein the heater material comprises aluminum nitride.

4. The article of claim 1, wherein the low volatile coating comprises:
an adhesion layer; and
a stack layer comprising alternating layers of aluminum nitride and a rare earth metal-containing material,
wherein the rare earth metal-containing material is selected from a group consisting of Y₂O₃, Y₃Al₅O₁₂ (YAG), Y₄Al₂O₉ (YAM), YF₃, YOF, Er₂O₃, Er₃Al₅O₁₂ (EAG), EF₃, EOF, La₂O₃, Lu₂O₃, Sc₂O₃, ScF₃, ScOF, Gd₂O₃, Sm₂O₃ or Dy₂O₃.

5. The article of claim 1, wherein the thermal conductivity is about 150 W/mK to about 200 W/mK.

6. The article of claim 1, wherein the heater material has a specific heat capacity of about 0.15 cal/g-° C. at 25° C. to about 0.30 cal/g-° C. at 25° C.

7. The article of claim 6, wherein the heater material with the low volatile coating has the specific heat capacity or an adjusted specific heat capacity that is within about ±5% of the specific heat capacity of the heater material without the low volatile coating.

8. The article of claim 1, wherein the rare earth metal-containing material is selected from a group consisting of Y₂O₃, Y₃Al₅O₁₂ (YAG), Y₄Al₂O₉ (YAM), YF₃, YOF, Er₂O₃, Er₃Al₅O₁₂ (EAG), EF₃, EOF, La₂O₃, Lu₂O₃, Sc₂O₃, ScF₃, ScOF, Gd₂O₃, Sm₂O₃ or Dy₂O₃.

9. The article of claim 1, wherein the low volatile coating has a thickness of about 75 nm to about 200 nm.

10. The article of claim 1, wherein the low volatile coating comprises:
an adhesion layer; and
a rare earth metal-containing layer, the rare earth metal-containing layer comprising a material selected from a group consisting of Y₂O₃, Y₃Al₅O₁₂ (YAG), Y₄Al₂O₉ (YAM), YF₃, YOF, Er₂O₃, Er₃Al₅O₁₂ (EAG), EF₃, EOF, La₂O₃, Lu₂O₃, Sc₂O₃, ScF₃, ScOF, Gd₂O₃, Sm₂O₃ or Dy₂O₃.

11. A method comprising:
performing atomic layer deposition (ALD) to deposit a low volatile coating on a component comprising a heater material with a thermal conductivity of about 50 W/mK to about 300 W/mK,
wherein the low volatile coating has a thickness of about 5 nm to about 5 μm,
wherein the low volatile coating reacts with a plasma to form reactants having a lower vapor pressure than reactants formed by reaction of the heater material with the plasma, and
wherein the heater material with the low volatile coating has the thermal conductivity or an adjusted thermal conductivity that is within about ±5% of the thermal conductivity of the heater material without the low volatile coating.

12. The method of claim 11, wherein the component is a high temperature heater.

13. The method of claim 11, wherein the heater material comprises aluminum nitride.

14. The method of claim 11, wherein the low volatile coating comprises:
an adhesion layer; and
a stack layer comprising alternating layers of aluminum nitride and a rare earth metal-containing material,
wherein the rare earth metal-containing material is selected from a group consisting of Y₂O₃, Y₃Al₅O₁₂ (YAG), Y₄Al₂O₉ (YAM), YF₃, YOF, Er₂O₃, Er₃Al₅O₁₂ (EAG), EF₃, EOF, La₂O₃, Lu₂O₃, Sc₂O₃, ScF₃, ScOF, Gd₂O₃, Sm₂O₃ or Dy₂O₃.

15. The method of claim 11, wherein the thermal conductivity is about 150 W/mK to about 200 W/mK.

16. The method of claim 11, wherein the heater material has a specific heat capacity of about 0.15 cal/g-° C. at 25° C. to about 0.30 cal/g-° C. at 25° C.

17. The method of claim 16, wherein the heater material with the low volatile coating has the specific heat capacity or an adjusted specific heat capacity that is within about ±5% of the specific heat capacity of the heater material without the low volatile coating.

18. The method of claim 11, wherein the rare earth metal-containing material is selected from a group consisting of Y₂O₃, Y₃Al₅O₁₂ (YAG), Y₄Al₂O₉ (YAM), YF₃, YOF, Er₂O₃, Er₃Al₅O₁₂ (EAG), EF₃, EOF, La₂O₃, Lu₂O₃, Sc₂O₃, ScF₃, ScOF, Gd₂O₃, Sm₂O₃ or Dy₂O₃.

19. The method of claim 11, wherein the low volatile coating has a thickness of about 75 nm to about 200 nm.

20. A method comprising:
performing atomic layer deposition (ALD) to deposit a low volatile coating on a high temperature heater comprising a heater material with a thermal conductivity of about 50 W/mK to about 300 W/mK,
wherein the low volatile coating has a thickness of about 5 nm to about 5 μm,
wherein the low volatile coating reacts with a plasma to form reactants having a lower vapor pressure than reactants formed by reaction of the heater material with the plasma, and
wherein the heater material with the low volatile coating has the thermal conductivity or an adjusted thermal conductivity that is within about ±5% of the thermal conductivity of the heater material without the low volatile coating,
wherein the low volatile coating uniformly covers exposed portions of the high temperature heater.
